(19) United States
(12) Patent Application Publication
(10) Pub. No.: US 2023/0178400 A1
(43) Pub. Date: Jun. 8, 2023

(54) LAMINAR FLOW DEVICE

(71) Applicant: NATIONAL TAIPEI UNIVERSITY OF TECHNOLOGY, Taipei City (TW)

(72) Inventors: SHIH-CHENG HU, Taipei City (TW); TI LIN, Taipei City (TW)

(21) Appl. No.: 18/046,152

(22) Filed: Oct. 12, 2022

(30) Foreign Application Priority Data
Oct. 15, 2021 (TW) 110138263

(51) Int. Cl. H01L 21/673; F24F 13/08

(52) U.S. Cl. CPC H01L 21/67389; F24F 13/082

(57) ABSTRACT

The present invention discloses a laminar flow device which includes a housing defining a cavity, at least one air inlet, a diffusion device and at least one uniform flow structure. The at least one air inlet is positioned within the housing. The diffusion device is positioned within the housing, and the at least one uniform flow structure is positioned within the bottom of the cavity.

### TECHNICAL FIELD

The present invention relates to a laminar flow device for generating a uniform airflow.

### BACKGROUND OF RELATED ARTS

Traditionally, considering that the wafer is a high-precision semiconductor material. Hence, it is usually placed in sealed carriers (e.g. FOUP/FOUB/MAC) during handling in the semiconductor process for avoiding moisture, gaseous pollutants such as ammonia, chlorine, hydrofluoric or hydrochloric acid, or fine pollutants such as particulates. However, these protections only keep the pollution-free storage environment only for the inside of the sealed carrier. In other words, when a user takes a wafer out from the sealed carrier for processing, the opening operation of the sealed carrier will possibly lead the above-mentioned pollutants into the sealed carrier. Furthermore, those pollutants will lower the yield due to the defect on the surface of the wafer. Therefore, how to effectively prevent the aforementioned pollutants from polluting the surface of the wafer when taking a wafer out of the sealed carrier for processing is a problem to be solved in the high-precision semiconductor process.

### SUMMARY

To solve at least one of the above problems, the present invention discloses a laminar flow device which comprises a housing, at least one air inlet positioned within the housing, at least one diffusion device positioned within the housing, and at least one uniform flow structure. At least one inner portion (part) of space of the housing defines a cavity, thus the uniform flow structure may be positioned within the bottom of the cavity. Accordingly, the space can be interconnected to the air inlet, the diffusion device, and the uniform flow structure, so that a gas can flow therein. Hence, the airflow of the space can be uniformly output to a uniform airflow by the internal pressure.

Specifically, the diffusion device further comprises at least one diffusion frame and at least one connecting space portion. The configuration may make the diffusion device connect to the cavity via the connecting space portion.

The above-mentioned descriptions are only preferred embodiments of the present invention and are not intended to limit the scope of implementation of the present invention. Therefore, all the shapes, structures, features, and spirits described in the scope of the patent application of the present invention shall be regarded as equivalent to the changes and modifications per se, and be included in the scope of the patent application of the present invention.

### BRIEF DESCRIPTION OF THE DRAWINGS

FIG. 1 is a schematic diagram of a partial embodiment of the laminar flow device of the present invention.

FIG. 2 is a schematic view of the housing of the laminar flow device of the present invention.

FIG. 3 is a schematic diagram of the diffusion device of the laminar flow device of the present invention.

FIG. 4 is another schematic diagram of the diffusion device of the laminar flow device of the present invention.

### DETAILED DESCRIPTION OF THE INVENTION

To make the description of the present disclosure more detailed and complete, the following description provides an illustrative description for the implementation and specific embodiments of the present invention.

The present invention is regarding as at least one embodiment of a laminar flow device, especially a laminar flow device used to generate a uniform airflow.

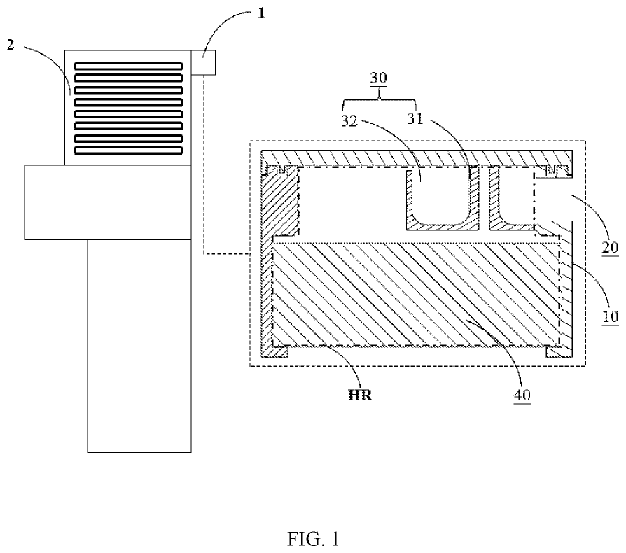

FIG. 1 is a schematic diagram of the laminar flow device of the present invention. FIG. 1. is to provide a laminar flow device 1, which is detachably mounted above a removable door of container 2 to generate a uniform airflow GL at the door. As shown in FIG. 1, the laminar flow device 1 at least comprises a housing 10, at least one air inlet 20 positioned within the housing 10, at least one diffusion device 30 positioned within the housing 10, and at least one uniform flow structure 40. Furthermore, a cavity HR is formed in a part of the housing 10, and the uniform flow structure 40 positioned within the bottom of the cavity HR. In this case, the cavity HR will connect the air inlet 20, the diffusion device 30 and the uniform flow structure 40, so that a gas SG flowing in the cavity HR which be uniformly output as the aforementioned uniform airflow GL. Further, the diffusion device 30 in this embodiment is formed from at least one diffusion frame 31 and at least one connecting space portion 32, and the diffusion device 30 can connect to the cavity HR through the connecting space portion 32.

Therefore, the dynamic pressure generated by the gas SG at the inlet hole 20 is converted into a static pressure by the diffusion frame 31, and after passing through the uniform flow structure 40, it is output in the direction of the door of the container 2 to form the aforementioned uniform airflow GL.

In the embodiment, the container 2 can be a semiconductor container such as Front Opening Unified Pod (FOUP) or Multi-Application Carrier (MAC). In addition, the gas SG can be Xtreme Clean Dry Air (XCDA) or Clean Dry Air (CDA). However, the gas SG can be an inert gas such as nitrogen gas, helium gas or argon gas, excepting the XCDA or CDA.

To make the gas GL more concentratively output, the ratio of the height to the length of the housing 10 can be 20%, and the ratio of the width to the length of the housing 10 ranges from 10 to 20%. Moreover, the air inlet 20 can have a diameter between 7 millimeters and 16 millimeters, preferably between 7 to 7.5 millimeters.

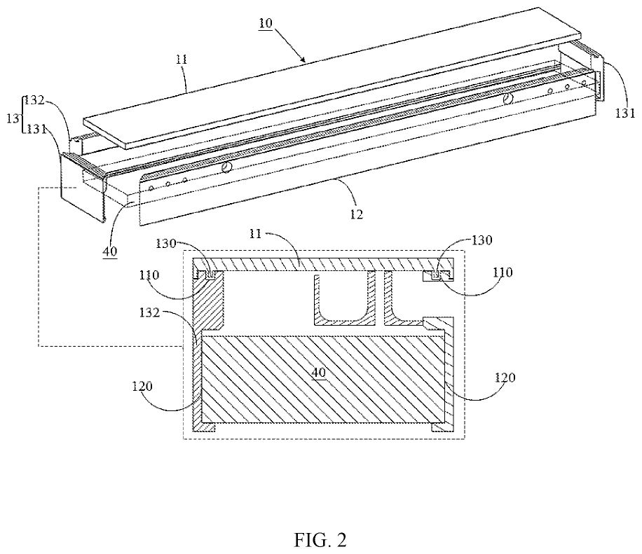

FIG. 2 is a schematic view of the housing 10 of the laminar flow device of the present invention. In the embodiment, the housing 10 is defined as a top cover 11, a partition 12, and an outer shell 13. As shown in FIG. 2, the cross-section of the outer shell 13 has an inverted-U shape, and the outer shell 13 comprises two supporting members 131 and a connecting member 132. The connecting member 132 is between the two supporting members 131, and two supporting members 131 respectively connect to the side of the partition 12. On the other hand, the top cover 11 is positioned on the outer shell 13, connecting with two supporting members 131, a connecting member 132, and the partition 12. In this case, the air inlet 20 can be set nearby the side of the partition 12 connecting the top cover 11. It makes the inner pressure in the housing 10 more easily increase with filling the gas SG from the air inlet 20.

In the embodiment, the outer shell 13 can be one-piece which is formed from two supporting members 131 and a connecting member 132. In addition, the outer shell 13 is not limited only to the above shown, which can be detachable, which is formed by connecting two supporting members 131 and a connecting member 132 with fasteners such as bolts or screws. Furthermore, the outer shell can be non-detachable, which is formed by two supporting members 131 and a connecting member 132 by gluing, riveting, welding, or pressing. The present invention is not limited thereto.

As discussed above, in the embodiment, the forming way of the housing 10 can be anyone as the description above. For example, the housing 10 can be one piece which is from the top cover 11, the partition 12, and the outer shell 13, or the housing 10 can be thereby composed of the top cover 11 and the partition 12, the top cover 11 and the outer shell 13, the partition 12 and the outer shell 13, or a top cover 11, the partition 12 and the outer shell 13. The connecting way of the above two components can be locking, gluing, riveting, welding, or pressing.

On the other hand, the top cover 11 of the housing 10 can be fixed to the diffusion frame 31 of the diffusion device 30 by the above-mentioned ways.

In the embodiment, the partition 12 and the outer shell 13 respectively have at least one first concave portion 110 and at least one second concave portion 120. The top cover 11 has at least one convex portion 130 which is aligned with the first concave portion 110. As shown in FIG. 2, when the top cover 11 connects with the partition 12 and the outer shell 13, the convex portion 130 is aligned with the first concave portion 110 with a gap between the convex portion 130 and the first concave portion 110. Simultaneously, the uniform flow structure 40 is positioned within the annular groove which is formed by the second concave portion 120, thus a user can replace the uniform flow structure 40 by dismantling and loading the top cover 11 and the partition 12.

In addition to locating the uniform flow structure 40 at the bottom of the cavity HR by the above-mentioned method, it can also locate by other ways based on the actual situation. For instance, a user can directly locate the uniform flow structure 40 at the bottom of the cavity HR by gluing. In some embodiments, the uniform flow structure 40 has irregular boundaries or jagged boundaries that can increase the contact area between the uniform flow structure 40 and the second concave portion 120, therefore making the uniform flow structure 40 locate better in the cavity HR.

As discussed above, the uniform flow structure 40 can be a ventilating plate, a porous plate, or a filter material layer. When the ventilating plate is used as the uniform flow structure 40, the plate can be made from a sintered polymeric material with a water absorption rate of less than 5% (but not include 0%), and the plate can have a thickness between 2.0 millimeters to 10.5 millimeters. The sintered polymeric material can be high-density polyethylene (HDPE), ultra-high molecular weight polyethylene (UPE), or mixtures thereof. The above ventilating plate is not limited be made from a sintered polymeric material, as long as it is a material with hydrophobic function, such as ceramics or metals.

Further, when the ventilating plate is used as the uniform flow structure 40, the diameter of the micropores of the plate ranges from 0.01 to 100 micrometer, and the preferable value of the afore-mentioned diameter is between 0.01 and 15 micrometer.

Also, when the porous plate is used as the uniform flow structure 40, the diameter of the micropores of the plate ranges from 0.5 to 3 millimeter. Otherwise, the plate can have a thickness between 0.1 and 5 millimeter.

When the filter material layer is used as the uniform flow structure 40, and the plate can be a single-layer or multi-layer high-efficiency filter (High-Efficiency Particulate Air, HEPA), a bag filter, a flat filter, or a combination thereof. The filter material layer can also combinate granular or powdered filter (e.g. granular activated carbon), hence the airflow can be output more stably.

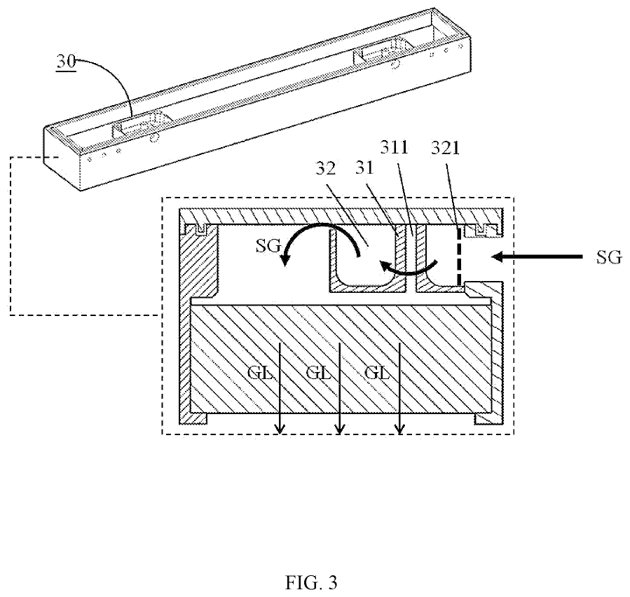

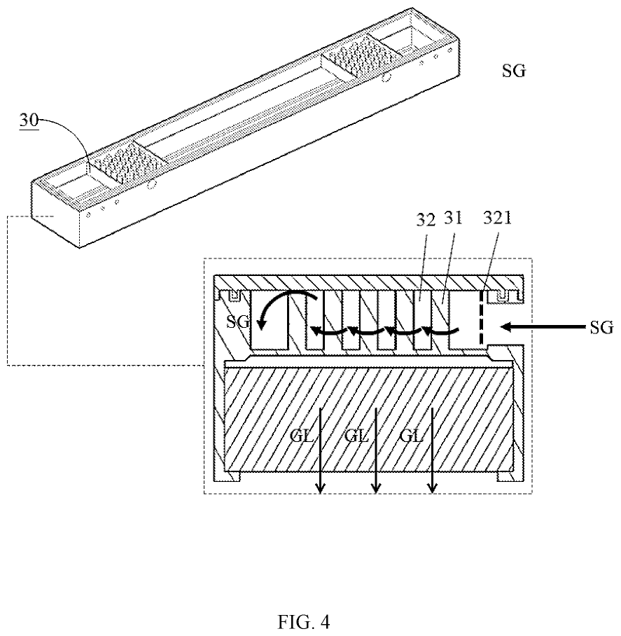

FIG. 3 and FIG. 4 illustrate a diffusion device 30 that can be used in the laminar flow device 1 as illustrated in FIG. 1. As shown in FIG. 3 and FIG. 4, the diffusion device 30 includes at least one connecting space portion 32 for making the inputting gas SG flow through; and at least one diffusion frame 31 expending in the down direction of the connecting space portion 32 that forms a closed loop hollow portion 311. Thereafter, when the gas SG diffuses to the cavity HR from the air inlet 20, increasing the internal pressure of the cavity HR through the connecting space portion 32. The gas SG diffuses outward from both sides of the connecting space portion 32 by guiding internal pressure or the diffusion frame 31. Moreover, the gas SG will convert to a uniform airflow GL which blocks external pollutions such as moisture, ammonia, chlorine, hydrofluoric acid or hydrochloric acid, particles, etc.

In the embodiment, the connecting space portion 32 of the diffusion device 30 and the air inlet 20 are parallel to each other, making an open end 321 of the connecting space portion 32 and the air inlet 20 align with each other. In other words, when the gas SG is filled at the air inlet 20, at least a part of the gas SG can directly enter the diffusion device 30 because the open end 321 is aligned with the air inlet 20.

Otherwise, the shape of the connecting space portion 32 is approximately forming a rectangle; and the shape of the diffusion device 30 is approximately forming a circle. However, the shapes of the invention are not limited there above, the connecting space portion 32 and the diffusion device 30 can be formed any shape, such as polygon, ellipse, and rectangle.

In addition, in the practical implementation of the present invention, the material of the connecting space portion 32 and the diffusion frame 31 is not limited, and can also be composed of well-known hydrophobicity materials, such as polystyrene (PS), polyethylene (PE), polypropylene (PP), ethylene-vinyl acetate copolymer (EVA), expanded polyethylene (EPE), expanded polystyrene (EPS) or other containing polyolefins. In fact, it can also be made of the same material as the uniform flow structure 40, such as high-density polyethylene (HDPE) or ultra-high molecular weight polyethylene (UPE).

The above-mentioned descriptions are only preferred embodiments of the present invention and are not intended to limit the scope of implementation of the present invention. Therefore, all the shapes, structures, features, and spirits described in the scope of the patent application of the present invention shall be regarded as equivalent to the changes and modifications per se, and be included in the scope of the patent application of the present invention.

What is claimed is:

1. A laminar flow device, comprising:
a housing defining a cavity;
at least one air inlet, positioned within the housing;
at least one diffusion device, connected with the at least one air inlet and positioned within the cavity; and
at least one uniform flow structure, positioned within the bottom of the cavity;
wherein the at least one diffusion device comprises at least one diffusion frame and at least one connecting space portion, and the at least one connecting space portion is connected with the cavity.

2. The laminar flow device as claimed in claim 1, wherein the housing is defined as a top cover, a partition and an outer shell.

3. The laminar flow device as claimed in claim 1, wherein the at least one diffusion frame having a hollow portion.

4. The laminar flow device as claimed in claim 1, wherein the at least one connecting space portion having an opening portion.

5. The laminar flow device as claimed in claim 1, wherein the uniform flow structure is ventilating plate, a porous plate, or a filter material layer.

6. The laminar flow device as claimed in claim 1, wherein the uniform flow structure has irregular boundary.

7. The laminar flow device as claimed in claim 2, wherein the outer shell comprises two supporting members and a connecting member; wherein the connecting member is between the two supporting members.

8. The laminar flow device as claimed in claim 2, wherein the top cover has at least one convex portion.

9. The laminar flow device as claimed in claim 8, wherein the partition and the outer shell respectively have at least one first concave portion which is aligned with the at least one convex portion.

10. The laminar flow device as claimed in claim 2, wherein the outer shell and the partition respectively have at least one second concave portion.
